(19) United States
(12) Patent Application Publication
(10) Pub. No.: US 2026/0362869 A1
(43) Pub. Date: Nov. 12, 2026

(54) ISOLATION OF MICRO LEDS BY INKJET PRINTING

(71) Applicant: Kateeva, Inc., Newark, CA (US)

(72) Inventors: Jianglong Chen, San Jose, CA (US); Christopher R. Hauf, Belmont, CA (US); Vivian Liu, Newark, CA (US); Nick Hsu, Newark, CA (US)

(73) Assignee: Kateeva, Inc., Newark, CA (US)

(21) Appl. No.: 19/515,676

(22) PCT Filed: Aug. 15, 2024
(86) PCT No.: PCT/US2024/042420

§ 371 Date: Mar. 2, 2026

Related U.S. Application Data
(60) Provisional application No. 63/581,785, filed on Sep. 11, 2023.

(51) Int. Cl. H10H 29/01; H10H 29/24

(52) U.S. Cl. CPC H10H 29/011; H10H 29/24

(57) ABSTRACT

Methods of processing a micro-LED substrate are described herein. The methods include depositing a deterrent material on a light-emitting surface of each micro-LED assembled on a micro-LED substrate and depositing a confinement material around each of the micro-LEDs, wherein the deterrent material prevents the confinement material from contacting the light-emitting surface of each of the micro-LEDs.

### FIELD

This patent application is about isolation and encapsulation of micron-scale LEDs, also called micro-LEDs. More specifically, methods are described herein for using inkjet printing to secure micro-LEDs assembled on a substrate.

### BACKGROUND

Micro-LEDs are becoming more widely used display components. Devices, such as watches, that have small-to medium-sized displays can use micro-LED displays. Some larger display devices are also being developed using stitched micro-LED tiles rather than LCD or OLED platforms. Micro-LEDs are generally disposed on a substrate and soldered or wired to circuitry to drive lighting the LEDs. During operation, repeated energizing and de-energizing of LEDs can cause thermal cycling that can weaken electrical connections of the LEDs. For this reason, among others, the LEDs are generally secured to the substrate using a structural confinement material that reduces thermal cycling. The structural confinement material must be applied between the LEDs, which are often spaced apart a few dozen microns, and generally must not access the light-emitting surface of the LEDs at all so the display effect of the LEDs is not compromised. There is a need for methods of packaging micro-LEDs that are very precise and cost-effective.

### SUMMARY

Embodiments described herein provide a method of treating a micro-LED substrate, the method comprising depositing a deterrent material on a light-emitting surface of each micro-LED assembled on a micro-LED substrate; and depositing a confinement material around each of the micro-LEDs, wherein the deterrent material prevents the confinement material from occluding the light-emitting surface of each of the micro-LEDs.

Other embodiments described herein provide a method of treating a micro-LED substrate, the method comprising depositing a deterrent material having a first hydrophobicity on a light-emitting surface of each micro-LED assembled on a micro-LED substrate; and depositing a confinement material having a second hydrophobicity around each of the micro-LEDs by a printing method, wherein the first hydrophobicity is greater than the second hydrophobicity by an amount such that the deterrent material prevents the confinement material from contacting the light-emitting surface of each of the micro-LEDs.

Other embodiments described herein provide a method of treating a micro-LED substrate, the method comprising depositing a superhydrophobic material on a light-emitting surface of each micro-LED assembled on a micro-LED substrate by microcontact deposition, transfer deposition, or inkjet printing; and depositing a confinement material comprising a silicone or acrylate polymer around each of the micro-LEDs by inkjet printing.

Other embodiments described herein provide a micro-LED substrate, comprising a plurality of micro-LEDs attached to a substrate by an electrically conductive material; a deterrent material disposed on a light-emitting surface of each micro-LED; and a confinement material disposed around each micro-LED, wherein the confinement material does not cover any portion of the light-emitting surface of any micro-LED.

### BRIEF DESCRIPTION OF THE DRAWINGS

FIG. 1A is a flow diagram summarizing a method of treating a micro-LED substrate according to one embodiment.

FIGS. 1B-1E are schematic side views of a substrate at various stages of the method of FIG. 1A.

FIG. 2 is a flow diagram summarizing a method of treating a micro-LED substrate according to another embodiment.

FIG. 3 is a flow diagram summarizing a method of treating a micro-LED substrate according to another embodiment.

FIG. 4 is a flow diagram summarizing a method of treating a micro-LED substrate according to another embodiment.

### DETAILED DESCRIPTION

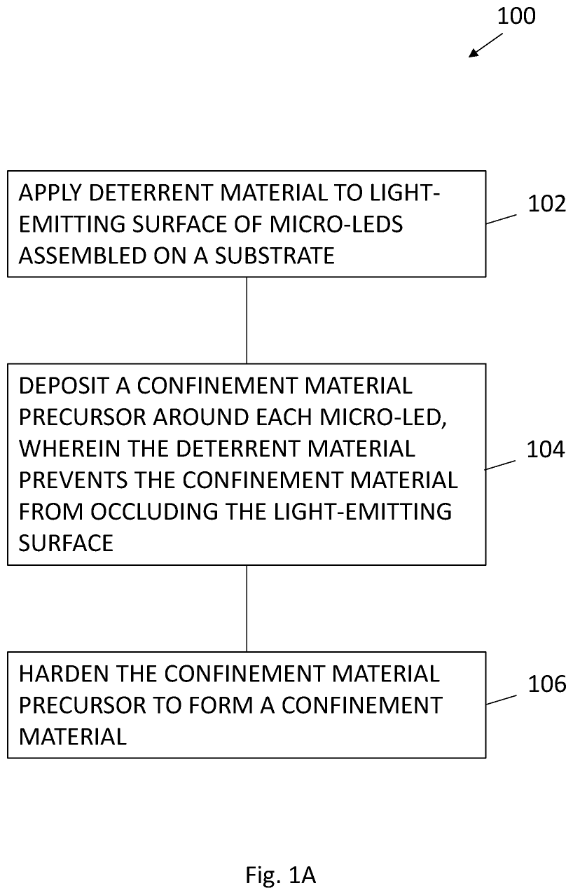

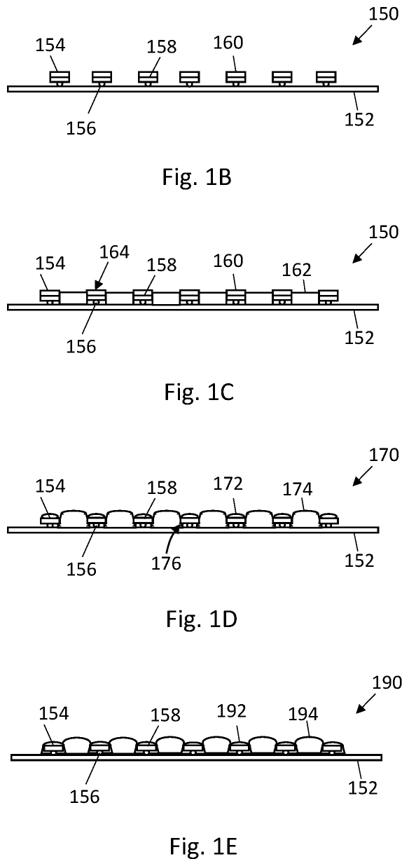

Methods for isolating and/or encapsulating micro-LEDs are described herein. These methods generally accomplish forming a confinement structure around each micro-LED in a plurality of micro-LEDs assembled on a substrate. Each micro-LED is attached to the substrate by an electrically conductive material, which may be solder, wire, bump, or combination thereof. FIG. 1A is a flow diagram summarizing a method 100 for treating a micro-LED substrate. FIGS. 1B-1X are schematic side views of a micro-LED substrate at various stages of the method 100. The micro-LEDs herein are micrometer-scale components having dimension generally less than about 200 μm, commonly less than 50 μm, for example 30 μm or 10 μm, and where multiple such components are disposed on a substrate, the components may be spaced apart at similar dimensions. The micro-LEDs may be rectangular in shape, or square, or circular, or elliptical, or another shape. Generally, the micro-LEDs have a light-emitting surface, and are arranged with the light-emitting surface facing away from the substrate. The light-emitting surface may be flat or curved in any suitable way, such as convex or concave.

At 102, a deterrent material is applied to the light-emitting surface of each micro-LED of a micro-LED substrate. The deterrent material is applied in a thin layer, for example a layer less than about 100 μm thick. The deterrent material is a material that will prevent any subsequently deposited material from occluding the light-emitting surfaces of the micro-LEDs by contacting or extending over the light-emitting surfaces of the micro-LEDs. To avoid diminishing emission of light from the light-emitting surfaces of the micro-LEDs, the deterrent material is generally transparent, or substantially transparent, to light at wavelengths emitted by the micro-LEDs.

The deterrent material may be physically deterrent or chemically deterrent. A physically deterrent material prevents a subsequently deposited material from occluding the light-emitting surface of a micro-LED by presenting a physical barrier preventing any subsequently deposited material from moving over or onto the light-emitting surface of any micro-LED. In effect, the physically deterrent material forms a small column over the light-emitting surface of the micro-LED so that any subsequently deposited material, deposited to a thickness or height less than the height of the physically deterrent material, cannot access any location on or over the light-emitting surface of the micro-LED.

The physically deterrent material may also have a surface feature that physically deters encroachment onto or over the light-emitting surface by a subsequently deposited material. For example, the physically deterrent material may have a surface roughness that prevents a subsequently deposited material from flowing across the surface of the deterrent material, effectively stopping any such encroachment at an edge of the deterrent material by a flow-stopping action of the surface roughness. In one aspect, a surface roughness can increase hydrophobicity of the deterrent material.

A chemically deterrent material uses chemical repulsion to prevent the subsequently deposited material from moving onto or over the light-emitting surfaces. The chemically deterrent material can be a hydrophobic material or superhydrophobic material, such as mineral oil or a hydrophobic polymer, and is generally selected to have hydrophobicity that is more than the subsequently deposited material to repel the subsequently deposited material from extending onto or over the light-emitting surfaces of the micro-LEDs. Where a chemically deterrent material is used, the deterrent material may be deposited in a thin layer, such as 100 μm or less, 20 μm or less, 5 μm or less, or 1 μm or less. In some cases, a molecular monolayer of chemically deterrent material can be applied to the light-emitting surfaces of the micro-LEDs.

FIG. 1B shows a micro-LED structure 150 that has a substrate 152 and a plurality of micro-LEDs 154 attached to the substrate 152, each micro-LED spaced apart from neighboring micro-LEDs and attached to the substrate 150 by an electrically conductive material 156. Each of the micro-LEDs 154 has a light-emitting surface 158 facing away from the substrate 150. The light-emitting surfaces are all shown as coplanar, but in reality will depart somewhat from strict coplanarity, for example by being at different heights and/or by being not strictly parallel.

The micro-LEDs 154 all have a deterrent material 160 deposited on a light-emitting surface 158 thereof, as in the method 100 of FIG. 1A at 102. The deterrent material 160 can be any of the materials described above, and can be formed in any suitable structure, such as a layer, which can be continuous, or a discontinuous collection of spots. All the deterrent materials 160 can be made of the same material, or different materials can be used to make the deterrent materials 160. For example, a first deterrent material 160 could be made of a first material and a second deterrent material 160, neighboring the first deterrent material or remote from the first deterrent material, can be made of a second material different from the first material. The deterrent material 160 can extend continuously from one edge of the light-emitting surface 158 to an opposite edge of the light-emitting surface 158. Here, the deterrent material 160 is represented as a continuous layer extending from one edge to an opposite edge of the light-emitting surface 158. In this case, the deterrent material 160 has a smooth planar surface that faces away from the light-emitting surface 158 and sharp edges. In other cases, the deterrent material 160 might have a non-planar surface, such as a curved surface, which may be convex or concave, or a rough surface, or any combination of smooth, rough, planar, and non-planar shapes. The deterrent material 160 might also have edges that are not sharp, but are curved or rounded to any suitable degree. Portions of an individual deterrent material 160 might have a combination of sharp and rounded corners, and different deterrent materials 160, applied to different micro-LEDs, can have shapes and edges that are different, some sharp, some rounded, some planar, and some non-planar according to the needs of an embodiment and the process, or combination of processes, used to form the deterrent materials 160.

Referring again to FIG. 1A, at 104, a confinement material precursor is deposited around each of the micro-LEDs, in the spaces between the micro-LEDs. The confinement material precursor is a flowable material that can be hardened to form a solid material between the micro-LEDs. The micro-LEDs may be spaced apart by a distance as small as 50 μm, such as 30 μm, for example 10 μm. To place the precursor material in such small spaces, the precursor material is deposited using a precision deposition method capable of accurately placing the confinement material precursor into spaces as small as 10 μm. Inkjet printing using industrial inkjet printers such as any of the YIELDJET® printers available from Kateeva, Inc., of Newark, California, can achieve such precision in deposition.

As noted above, the deterrent material formed prior to depositing the confinement material precursor acts to prevent the confinement material precursor from occluding the light-emitting surface of the micro-LEDs by preventing the precursor from extending over or contacting any of the light-emitting surfaces of the micro-LEDs. Thus, accurate deposition of the confinement material precursor in the spaces around the micro-LEDs is facilitated by action of the deterrent material, enabling the high throughput industrial inkjet printers available today to deposit the confinement material precursor with suitable accuracy.

At 106, the micro-LED structure is subjected to processing that hardens the confinement material precursor into a confinement material. The processing can include exposing the substrate to radiation to cause the confinement material precursor to harden. The radiation can cause a polymerization reaction in the confinement material precursor. Alternately or additionally, the radiation can vaporize liquid from the confinement material precursor, solidifying the precursor to form the confinement material. The processing can also include, alternately or additionally, exposing the substrate to thermal energy to harden the precursor by any of the mechanisms described above. A combination of radiation and thermal energy can also be used.

FIG. 1C is a schematic side view of the micro-LED structure 150 after deposition and processing of the confinement material precursor around the micro-LEDs 154 to form a confinement material 162, according to the method 100 of FIG. 1A at 104 and 106. The micro-LED structure 150 shown in FIG. 1C is thus made using the method 100 of FIG. 1A. The confinement material 162, in this case, in liquid state before hardening, fills the space between the micro-LEDs 154 and extends from a first deterrent material 160 of a first micro-LED 154 to a second deterrent material 160 of a neighboring micro-LED 154. Here, the confinement material 162 has a smooth flat upper surface that extends from the first deterrent material to the second deterrent material. After hardening, the confinement material shown in FIG. 1C has a thickness that is greater than a height of the light-emitting surfaces 158 of the micro-LEDs above the surface of the substrate 152 facing the micro-LEDs, but less than a height of exposed surfaces 164 of the deterrent materials 160. In other embodiments the hardened confinement material 162 might have thickness less than the height of the light-emitting surfaces 158 or greater than the exposed surfaces of the deterrent material 160.

FIG. 1D is a schematic side view of another micro-LED structure 170 after formation of a deterrent material 172 and a confinement material 174 thereon according to the method 100 of FIG. 1A. In this case the deterrent material 172 is chemically deterrent, and the confinement material precursor is chosen to respond to proximity with the deterrent material by forming a curved upper surface. It is believed that, in such cases, the confinement material precursor has a net surface repulsion response to the deterrent material 172. That is, it is believed that chemical affinity between molecules of the confinement material precursor is greater than any chemical affinity between molecules of the confinement material precursor and molecules of the deterrent material, resulting in a surface tensile energy that forms the surface of the confinement material precursor into a curved shape. Here, the deterrent material 172 is formed to have a dome shape, in this case an elliptical or quasi-elliptical shape, that extends almost from one edge of the light-emitting surface 158 to an opposite edge of the light-emitting surface 158, on each of the micro-LEDs 154. The deterrent material 172 can extend to one or more of the edges of each micro-LED, or even a bit beyond the edges if deposited as a liquid with surface tension and then hardened in a way that does not substantially reduce the volume of the deposited deterrent material.

The confinement material precursor, while liquid, withdraws from the deterrent material 172 to form a convex upper surface such that the confinement material precursor does not extend over or occlude the light-emitting surfaces 158 of the micro-LEDs, even though the confinement material 174 is deposited to a height greater than a height of the deterrent material 172. It should be noted that the deterrent material 172 may have a flat smooth upper surface, as in the embodiments of FIGS. 1B and 1C while the confinement material has a curved shape.

Also, in this case, the confinement material 174, in a liquid state, is seen to spread along the substrate 152 when deposited. The liquid confinement material here extends along the substrate 152 into a space between the micro-LEDs 154 and the substrate 152, where such space is not entirely filled by the electrically conductive material 156. The confinement material 174, in a hardened state after processing at 106 in the method 100, thus has a foot 176 that extends under each micro-LED 154. Spreading behavior of the confinement material in a liquid state can be selected by adjusting the viscosity of the liquid confinement material, for example by including an amount of solvent, or low molecular weight monomer, in the liquid confinement material selected to provide the desired spreading behavior. It should also be noted that a surface of the substrate 152 can be prepared, if desired, to prevent any spreading of the confinement material when deposited as a liquid. For example, a material that is the chemically incompatible with the confinement material can be thinly coated onto the substrate 152 prior to depositing the liquid confinement material such that the liquid confinement material forms a high contact angle with the substrate surface and does not spread. In most cases, the confinement material is at least somewhat hydrophobic, so a material substantially more hydrophilic than the confinement material, such as a hydrophilic polymer, can be coated onto the substrate 152 before deposition of the liquid confinement material to prevent spreading of the liquid confinement material.

FIG. 1E is a schematic side view of another embodiment of a micro-LED structure 190 after formation of a deterrent material 192 and a confinement material 194 according to the method 100 of FIG. 1A. In this case, the deterrent material 192 is formed over and around the micro-LEDs 154 to fully encapsulate the micro-LEDs with a small deterrent structure. Here the deterrent material 192 has a smooth, curved upper surface, but as noted above the upper surface of the deterrent material 192 can be flat and can be smooth or rough. The deterrent material 192, in this case, has a tapered shape emerging from the type of material and deposition process. In this case, the deterrent material 192 was deposited as a liquid using a relatively viscous material that forms a convex droplet upon deposition onto the substrate 152 and over the micro-LEDs 154.

It should be noted that the deterrent materials and confinement materials described herein can be a single material or a combination of materials. For example, a deterrent material can be formed as a composite deterrent material by forming a first deterrent material on, over, or around a micro-LED and then forming a second deterrent material on, over, or around the first deterrent material and the micro-LED. Likewise, a composite confinement material can be formed by forming a first confinement material on the substrate 152 and forming a second confinement material on the first confinement material. The composite, in each case, can include any suitable number of different materials, and a composite structure can be used to achieve any desired shape of the deterrent material, the confinement material, or both. Thus, for example, a composite structure can be formed, for the deterrent material, the confinement material, or both, by using a first liquid material having a first viscosity and a second material having a second viscosity, which can be more or less than the first viscosity. The two materials can be hardened at the same time, or the first material can be hardened before the second material is deposited. In this way, precise placement and shaping of the deterrent and confinement materials can be controlled.

The deterrent material can be a material that is substantially hydrophobic and/or superhydrophobic. The deterrent material can have a roughened surface that enhances hydrophobicity of the deterrent material. For example, the deterrent material can be an oil, such as mineral oil, a fluoropolymer, such as Teflon (polytetrafluoroethylene, PTFE), or a combination thereof. Other polymers, such as polyvinylidene fluoride (PVDF), polyethersulfone (PESU), ethylene chlorotrifluoroethylene (ECTFE), polyether ether ketone (PEEK), polyamide imide (PAI), and polyphenylene sulfide (PPS), can also be used alternately or additionally, any of which can be modified to increase hydrophobicity. For example, PPS can be carboxylated and reacted with chitosan according to known methods to form a superhydrophobic polymer that can be coated onto a surface, as described herein.

The deterrent material applied to the light-emitting surfaces of the micro-LEDs should be transparent (or effectively transparent, for example having optical density, at relevant wavelengths, of 10⁻³ or less) at wavelengths emitted by the micro-LEDs. Curable materials that cure as transparent polymers can be used, so long as they have, or are modified to have, sufficient hydrophobicity to chemically deter encroachment of a confinement material, or are deposited to a thickness to provide a physical deterrent to encroachment. The YIELDJET® inks available from Kateeva, Inc., of Newark, California, can be used as transparent materials for forming physically deterrent materials, and can be modified to increase hydrophobicity for use as chemically deterrent materials, for example by surface modification and or compositing with superhydrophobic materials such as PTFE. Such materials can also be used as physically deterrent materials.

The deterrent material can also be a mixture of a superhydrophobic material with a less hydrophobic material. For example, the deterrent material can be a polymer, such as a silicone or acrylate polymer, that has particles of a superhydrophobic material applied to the top or included in the polymer. In one case, a silicone or acrylate polymer could include fluoropolymer particles to make a deterrent material that is more hydrophobic than the silicone or acrylate material. A superhydrophobic material, such as mineral oil, can be used as a chemical deterrent, and can be applied in a monolayer to the surface of the micro-LEDs. A monolayer of a superhydrophobic material such as mineral oil can chemically deter encroachment of a less hydrophobic confinement material. A monolayer of a superhydrophobic material can also be applied to a surface of another deposited material to form a composite deterrent material that is chemically deterrent. For example, a monolayer of mineral oil can be applied to a surface of a polymer, such as a silicone or acrylate polymer, deposited and hardened on the light-emitting surface of a micro-LED to form a chemically deterrent material. In such cases, the deterrent material has a support portion, which is the silicone or acrylate polymer, and a deterrent portion, which is the monolayer of mineral oil. Such composite deterrent materials, having layers of materials with different deterrent characteristics and capacities, can be made from any suitable materials, with layers having any useful thicknesses and arrangements.

Particles can be included in the deterrent material to form a roughened surface that is superhydrophobic. For example, hydrophobic silica (H-SiO₂) particles can be included in a polymer, such as any of the polymers mentioned above by adding the silica particles to unpolymerized monomers and then polymerizing the monomers. The silica-monomer mixture can be deposited as a liquid and then polymerized. Viscosity of the liquid mixture can be adjusted using suitable solvents so the monomer-particle mixture is not too viscous to be deposited. In another method, such silica particles can be dispersed, along with polymer particles, in a solvent and applied to a surface. After drying, a superhydrophobic coating can be obtained in many cases. For example, H-SiO₂ particles can be dispersed, along with PPS particles, in ethanol, applied to a surface, and dried to form a superhydrophobic coating. Such methods can also be used with less hydrophobic materials, such as PEEK, to form superhydrophobic coatings. For example, a PEEK/PTFE composite can be made that can provide a superhydrophobic coating.

The deterrent material can be applied as a liquid material or as a vapor material. Applying the deterrent material as a liquid material is followed by a hardening process to solidify the deterrent material. Applying the deterrent material as a vapor material typically results in a solid material on the light-emitting surfaces, but in some cases the deterrent material can be condensed onto the light-emitting surfaces, from vapor to liquid, and then solidified. A CVD material that can be used as a deterrent material is the NOTAK® CVD coating available from Silcotek Technologies of Bellefonte, Pennsylvania. This coating forms a solid material from a CVD process. The coating can be applied to all component of the micro-LED substrate or a mask can be used to prevent coating any features other than the light-emitting surfaces of the micro-LEDs.

The confinement material can be a material that, in liquid state, has polymerizable components, such as monomers and oligomers, that can polymerize when stimulated by appropriate energy. For example, the confinement material can be an acrylate monomer mixture, a siloxane monomer mixture, or a combination thereof. Examples of materials that can be used as a confinement material include any of the UVR series of Legend Inks available from Taiyo America, Inc., of Carson City, Nevada. Acrylate and/or silicone copolymers and multipolymers, such as acrylate urethane copolymers, acrylate styrenic copolymers, acrylate alpha olefin copolymers, acrylate epoxy copolymers, acrylate ether copolymers, siloxane ether copolymers, siloxane acrylate copolymers, siloxane epoxy copolymers, siloxane urethan copolymers, and the like, and terpolymers and multipolymers of such components, can be used. In general, any photopolymer, thermoset polymer, or photothermal polymer (polymer formed by application of combined radiation and thermal energy to a polymerizable mixture) that hardens to form a structurally strong material can be used as a confinement material.

The confinement material can be, or can contain, an optical enhancement material. The optical enhancement can be refractive, reflective, diffusive, scattering, spectral, absorptive, emissive, filtering, or a combination thereof. For example, the confinement material can include scattering particles, such as oxide particles (e.g. titanium oxide, aluminum oxide, silicon oxide, etc.), nitride particles (e.g. silicon nitride, titanium nitride, aluminum nitride, etc.), oxynitride particles (silicon oxynitride, titanium oxynitride, etc.), metal particles (silver, zinc, alloy, etc.), or a combination thereof. In another example, the confinement material can include quantum dots that absorb light at one wavelength and emit light at another wavelength. In another example, the confinement material can include a dye, a phosphorescent material, a notch filter, a birefringent material, a black material (e.g. carbon black), or a combination thereof. Any combination of all the above materials can be included in, incorporated into, or added to the confinement material. Such materials can offer optical effects, such as light spreading, light focusing, wavelength conversion, light softening, and the like.

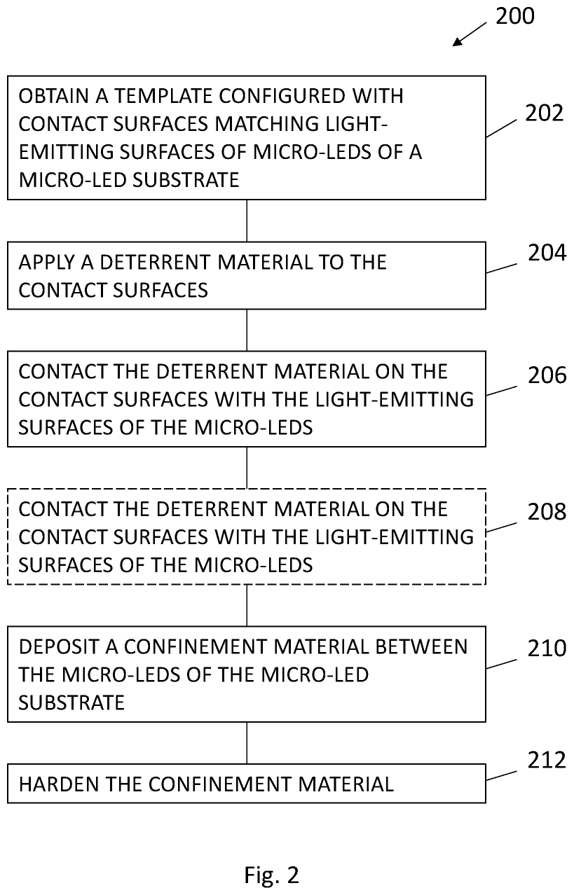

The deterrent material can be formed on the micro-LEDs in many different ways. FIG. 2 is a flow diagram summarizing a method 200 of treating a micro-LED substrate according to one embodiment. The method 200 features forming a deterrent material on micro-LEDs of the micro-LED substrate by microcontact printing or microstamping, which are both contact methods. At 202, a microcontact printing article is obtained that can be used to apply material to the light-emitting surfaces of the micro-LEDs. The microcontact printing article is an object that is configured to have a plurality of contact surfaces matching the light-emitting surfaces of the micro-LEDs. Such an article can be made according to any suitable additive or subtractive process. For example, a mold can be used to form a microcontact printing article having the plurality of contact surfaces. Alternately, a polymeric article article can be formed and then the plurality of contact surfaces can be patterned into the polymeric article by a lithography technique, such as photomask lithography, beam-writing lithography (laser, ion, electron, proton), or imprint lithography to form the microcontact printing article. As a further alternative, a polymeric article having the plurality of contact surfaces can be 3D-printed.

The contact surfaces are small, like the micro-LEDs, and may be formed as surfaces of small pillars to facilitate cleanly loading the contact surfaces with a material to be applied to the light-emitting surfaces of the micro-LEDs. In one case, a master mold can be formed using a photoresist such as SU-8 on a substrate, using a lithography process. A pattern matching the pattern of light-emitting surfaces exhibited by the micro-LEDs of a micro-LED substrate to be treated can be lithographically formed in an SU-8 photoresist to form a master mold. The SU-8 master mold can be used to form polymeric articles from a material like silicone, or other suitable polymeric material. The master mold can provide a pattern for contact surfaces of the polymeric article to be used for microcontact printing. A similar molding process can be used to form a fluid reservoir to be used to apply material to the contact surfaces of the polymeric article. For example, a negative pattern corresponding to the pattern of light-emitting surfaces of the micro-LED substrate can be lithographically formed in an SU-8 photoresist to form a negative master mold that can be used to form a reservoir article matching the polymeric article to be used for microcontact printing. The reservoir article has a plurality of reservoirs that can receive the pillars of the microcontact printing article to precisely and cleanly apply a material to the ends of the pillars of the microcontact printing article.

At 204, a deterrent material is applied to the contact surfaces of the microcontact printing article. As described above, this can be done using a reservoir article configured to match the contact surfaces of the microcontact printing article. Alternately, a continuous thin film of the deterrent material can be coated onto a substrate, and then the contact surfaces of the microcontact printing article can be pressed against the film to load the contact surfaces with the deterrent material. In other methods, the deterrent material can be applied to the contact surfaces by spraying, rolling, condensing, or other suitable method.

At 206, the contact surfaces of the microcontact printing article, loaded with deterrent material, are brought into contact with the light-emitting surfaces of the micro-LEDs of a micro-LED substrate of the sort described herein. The microcontact printing article is aligned with the micro-LED substrate using any suitable means, such as a precision robot controlled by a controller using a camera as image input to position the robot, and the deterrent material on the contact surfaces of the microcontact printing article is touched to the light-emitting surfaces of the micro-LEDs. A touching force can be applied to the light-emitting surfaces of the micro-LEDs to ensure transfer of the deterrent material from the contact surfaces of the microcontact printing article to the light-emitting surfaces. If desired, an excess amount of the deterrent material can be applied, and a touching force can be used to create a spreading of the deterrent material during microcontact printing. Thus, an area of the light-emitting surfaces can be covered with deterrent material that is greater than an area of the contact surfaces of the microcontact printing article.

Where microcontact printing is used to apply a deterrent material to the light-emitting surfaces of micro-LEDs, the deterrent material is generally a chemically deterrent material because microcontact printing typically cannot provide a height of the deterrent material to provide physical deterrence. Thus, where microcontact printing is used, the deterrent material is typically a superhydrophobic material, which may be homogeneous or composite as described herein. For example, mineral oil can be used as the deterrent material in the method 200.

At 208, the micro-LED substrate can be optionally processed to optimize the deterrent material. The processing can include hardening, surface modification, leveling, and/or subsequent microcontact printing. Hardening can include exposing the deterrent material to radiation and/or thermal energy. Surface modification can include adding or subtracting material at the surface of the deterrent material, for example adding a superhydrophobic liquid or solid to the surface of the deterrent material. Leveling can include idling the substrate for a period. Leveling can also include applying energy, such as vibration energy or thermal energy, to promote flowing and settling of the deterrent material. Subsequent microcontact printing can add a superhydrophobic layer to the deterrent material or can implant any suitable material at the surface of the deterrent material. Any combination of subsequent processing techniques can be used.

At 210, a confinement material is deposited between the micro-LEDs of the micro-LED substrate. The confinement material can be deposited as a liquid using an inkjet printing process in which a pattern of the micro-LEDs is provided to an inkjet printer as a template, and the inkjet printer prints droplets of the confinement material according to the template. Such printing processes can generally be performed using any industrial scale inkjet printer, such as any of the YIELDJET® printers available from Kateeva, Inc., of Newark, California.

The confinement material can be deposited to any suitable depth. As described herein, the confinement material can be deposited to a depth that is less than a height of the light-emitting surfaces of the micro-LEDs or the confinement material can be deposited to a depth that is greater than the height of the light-emitting surfaces. Generally, where microcontact printing is used to apply a deterrent material, as above, the confinement material can be deposited to a depth that is less than or greater than the height of the light-emitting surfaces. Where the depth is greater than the light-emitting surfaces, and where a material is used for the confinement material that is susceptible to chemical deterrence by a hydrophobic or superhydrophobic material, the confinement material will withdraw from the space above the deterrent material and the light-emitting surfaces of the micro-LEDs to provide physical confinement of the micro-LEDs without occluding the light-emitting surfaces thereof.

At 212, the confinement material is hardened by application of radiation energy, thermal energy, or both. Ultraviolet radiation is commonly used, but any combination of energies can be used, including infrared, ultraviolet, visible, and thermal energy.

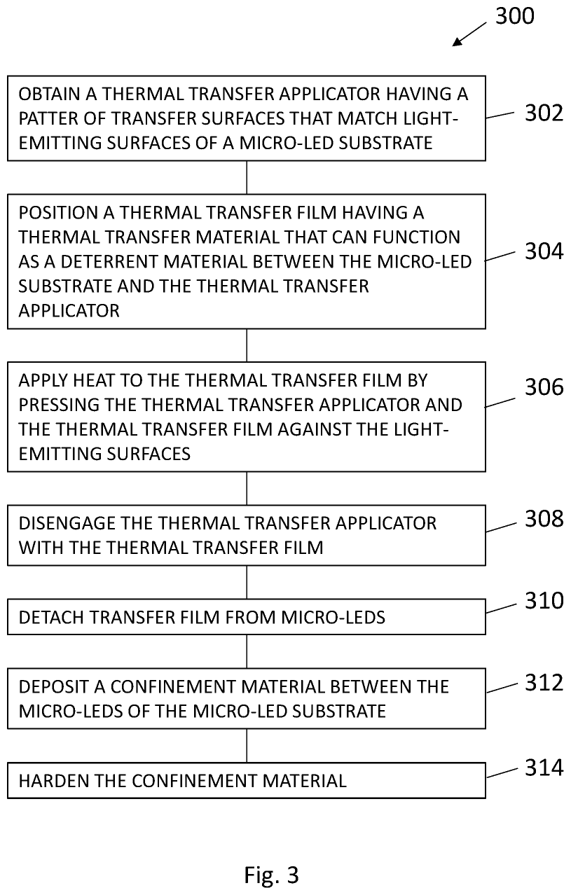

Other methods can be used to apply a deterrent material to light-emitting surfaces of micro-LEDs. FIG. 3 is a flow diagram summarizing a method 300 of treating a micro-LED substrate according to another embodiment. The method 300 uses thermal transfer printing to apply a deterrent material to light-emitting surfaces of micro-LEDs. Thermal transfer printing generally uses a transfer film with a patterned heat applicator to apply heat to the transfer film at locations where material is to be transferred from the transfer film to a substrate.

At 302, a thermal transfer applicator is obtained having a pattern of transfer surfaces that matches a pattern of light-emitting surfaces of micro-LEDs on a micro-LED substrate. The transfer surfaces may exactly match dimensions of the light-emitting surfaces or the transfer surfaces may differ in dimensions from the light-emitting surfaces by an amount selected to optimize application of transfer material to the light-emitting surfaces. For example, lateral expansion or contraction of the transfer material upon contact with the light-emitting surfaces may be compensated or taken into account in selecting dimensions of the transfer surfaces.

At 304, a thermal transfer film is positioned between the transfer surfaces of the transfer applicator and the light-emitting surfaces of the micro-LEDs. The transfer surfaces may be aligned with the light-emitting surfaces using any suitable method, as described above. The transfer film typically includes a polymer or metal backing film that has a transfer material applied to one side of the film. The backing film is intended to contact a heat applicator, such as the transfer applicator of 302. Application of heat to the backing film releases transfer material from the transfer film for deposition on a substrate. The transfer material is typically a material that is heat stable but melts at an appropriate temperature for thermal transfer printing. One example of a transfer material that can be used is a polyester material. Hydrophobicity of such a material could be increased by suspending fluoropolymer particles in the polyester. Such a material could be coextruded onto a transfer film for use in a method like the method 300.

At 306, the transfer applicator is urged against the light-emitting surfaces of the micro-LEDs with the thermal transfer film between. The transfer material is placed in direct contact with the light-emitting surfaces while the transfer applicator applies heat and pressure to the backing film of the transfer film. Heat from the applicator causes the transfer material to adhere to the light-emitting surfaces of the micro-LEDs and to comparative de-adhere from the backing film. The heat from the applicator may melt the transfer material such that the transfer material becomes a liquid that can preferentially adhere to the light-emitting surfaces.

At 308, the applicator is disengaged with the transfer film, interrupting application of heat to the transfer film and the transfer material. The transfer material that is in contact with both the backing film and the light-emitting surfaces of the micro-LEDs cools, and if liquid solidifies.

At 310, the transfer film is detached from the micro-LEDs (for example by peeling), leaving transfer material adhered to the light-emitting surfaces of the micro-LEDs. The transfer material adhered to the light-emitting surfaces becomes a deterrent material. Thickness of the deterrent material is determined by thickness of the transfer material of the transfer film. The thickness of the deterrent material may be equal to the thickness of the transfer material attached to the backing layer of the transfer film, or the thickness of the deterrent material may be more or less than the thickness of the transfer material attached to the transfer film, depending on delamination of the transfer material from the backing film and on behavior of the transfer material in contact with the light-emitting surfaces of the micro-LEDs. In general, as described above, thickness of the transfer material on the light-emitting surfaces is selected to provide a desired performance as a deterrent material. A less hydrophobic material can be formed with a thickness that can provide a physical deterrent to the spread of confinement material across the light-emitting surface. A more hydrophobic material can take advantage of chemical deterrence, and so can be applied to a smaller thickness.

At 312, a confinement material is applied to the micro-LED substrate between the micro-LEDs, as described above, and at 314, the confinement material is hardened, as described above.

The method 300 can be performed using transfer methods other than thermal transfer printing. Some such methods include rotating drum transfer printing and gravure offset printing. Any transfer printing process having capability to transfer micron-scale materials to a substrate can be used.

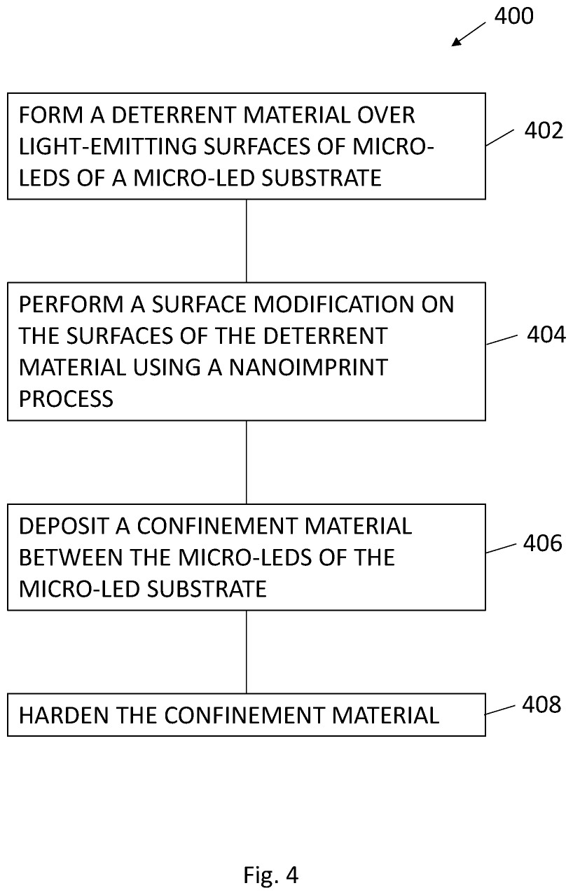

FIG. 4 is a flow diagram summarizing a method 400 of treating a micro-LED substrate according to another embodiment. The method 400 uses a nanoimprint operation to adjust surface characteristics of a deterrent material to make the deterrent material resistant to a confinement material. At 402, a deterrent material is formed over the light-emitting surface of micro-LEDs of a micro-LED substrate. The deterrent material can be formed only on the light-emitting surfaces or entirely around the micro-LEDs, covering the light-emitting surfaces and leaving space between the micro-LEDs. The deterrent material can be deposited as a liquid material and subsequently hardened. The deterrent material can be deposited only on the light-emitting surfaces or around the micro-LEDs and covering the light-emitting surfaces, leaving space between the micro-LEDs. The deposited material can have a flat or curved, for example convex, surface. The liquid deterrent material can be deposited by any suitable precision deposition method, including inkjet printing, and any of the materials described above for a deterrent material can be used. The liquid material is hardened, using any suitable method, to form the deterrent material. Methods described herein can be used.

At 404, a surface modification is applied to the deterrent material by a nanoimprint process. A nanoimprint applicator is obtained that has a pattern of imprint surfaces matching the pattern of light-emitting surfaces of the micro-LED substrate. The imprint surfaces of the nanoimprint applicator are typically made of a hard material that is resistant to breaking under compression such as stainless steel. Very hard, non-brittle plastic, such as polypropylene or polyurethane, can also be used as the material for the imprint surfaces. The nanoimprint applicator can have a homogeneous composition (i.e. be made entirely of stainless steel or hard polymer) or can be a composite article with a support portion made of a different material from the imprint surfaces.

The surface modification can be a roughening of the surface of the deterrent material merely by changing the surface morphology of the material. Alternately, or additionally, the surface modification can add a material to the surface of the deterrent material. The imprint surfaces of the nanoimprint applicator are brought into direct contact with the deterrent material formed on the light-emitting surfaces of the micro-LEDs in a way that increases roughness of the surfaces, either by creating texture in the surfaces or by adding a particulate material to the surfaces. The imprint surfaces of the nanoimprint applicator can have a surface texture or pattern that at least partially transfers to the surfaces of the deterrent material by application of pressure from the imprint surfaces to the deterrent material surfaces. Alternately, or additionally, a particulate material can be temporarily adhered to the imprint surfaces of the nanoimprint applicator prior to contact with the deterrent material, such that upon contact with the deterrent material the particulate material is impressed into the surfaces of the deterrent material to add roughness. The particulate material can additionally be a superhydrophobic material to increase the effect of the surface modification.

The surface modification generally increases resistance of the deterrent material surface to encroachment by the confinement material to be applied between the micro-LED's. At 406, the confinement material is deposited around the micro-LEDs and at 408 the confinement material is hardened, as in the methods 200 and 300. As in the methods 200 and 300, the confinement material can be deposited to a depth that is less than or greater than the height of the light-emitting surfaces of the micro-LEDs.

The methods described herein can be used to isolate, encapsulate, and confine micro-LEDs on a micro-LED substrate without impacting light emission by the micro-LEDs. Use of a deterrent material provides a precise method of preventing encroachment of a confinement material, deposited between the micro-LEDs, onto or over the light-emitting surfaces of the micro-LEDs. The deterrent material allows high-precision non-contact methods, such as inkjet printing, to be used to deposit the confinement material in a pattern in the spaces between the micro-LEDs and then harden the confinement material to prevent unwanted shifting of micro-LEDs on the substrate. Liquid deposition methods available for such depositions are fast and precise, enabling micro-LED substrates to be finished with high throughput. The precise placement of confinement material in the spaces between the micro-LEDs prevents unwanted optical effects of continuous encapsulant materials formed over and between the micro-LEDs. Because there is no continuous material to conduct light from one micro-LED into the space between the micro-LEDs, light emission from the micro-LEDs is precisely controlled.

While the foregoing is directed to embodiments of one or more inventions, other embodiments of such inventions not specifically described in the present disclosure may be devised without departing from the basic scope thereof, which is determined by the claims that follow.

1. A method of treating a micro-LED substrate, the method comprising:
depositing a deterrent material on a light-emitting surface of each micro-LED assembled on a micro-LED substrate; and
depositing a confinement material around each of the micro-LEDs, wherein the deterrent material prevents the confinement material from occluding the light-emitting surface of each of the micro-LEDs.

2. The method of claim 1, wherein the deterrent material is more hydrophobic than the confinement material.

3. The method of claim 1, wherein the deterrent material is deposited by a contact method.

4. The method of claim 1, wherein the confinement material is deposited by printing.

5. The method of claim 4, wherein the deterrent material is deposited by printing.

6. The method of claim 1, further comprising hardening the confinement material.

7. The method of claim 6, wherein hardening the confinement material comprises exposing the confinement material to radiation.

8. The method of claim 1, wherein the micro-LEDs are attached to a surface of the substrate by an electrically conductive material.

9. The method of claim 8, where in the micro-LEDs have a first thickness, in a direction perpendicular to the surface of the substrate, the confinement material has a second thickness, in the direction perpendicular to the surface of the substrate, and the second thickness is larger than the first thickness.

10. The method of claim 1, wherein the confinement material contains an optical enhancement material.

11. The method of claim 10, wherein the optical enhancement material is a refractive material, a reflective material, an absorptive material, a scattering material, or an emissive material.

12. The method of claim 1, wherein the deterrent material includes a hydrophobic substance.

13. A method of treating a micro-LED substrate, the method comprising:
depositing a deterrent material having a first hydrophobicity on a light-emitting surface of each micro-LED assembled on a micro-LED substrate; and
depositing a confinement material having a second hydrophobicity around each of the micro-LEDs by a printing method, wherein the first hydrophobicity is greater than the second hydrophobicity by an amount such that the deterrent material prevents the confinement material from contacting the light-emitting surface of each of the micro-LEDs.

14. The method of claim 13, wherein the deterrent material is a superhydrophobic material.

15. The method of claim 13, wherein the deterrent material contains a superhydrophobic material.

16. The method of claim 13, wherein the deterrent material is deposited by a contact method and the confinement material is deposited by a non-contact method.

17. The method of claim 15, wherein the confinement material contains an optical enhancement material.

18. A method of treating a micro-LED substrate, the method comprising:
depositing a superhydrophobic material on a light-emitting surface of each micro-LED assembled on a micro-LED substrate by microcontact printing, transfer deposition, or inkjet printing; and
depositing a confinement material comprising a silicone or acrylate polymer around each of the micro-LEDs by inkjet printing.

19. The method of claim 18, wherein the superhydrophobic material is a polymer that contains a superhydrophobic particle.

20. The method of claim 18, wherein the confinement material contains an optical enhancement material.

21. A micro-LED substrate, comprising:
a plurality of micro-LEDs attached to a substrate by an electrically conductive material;
a deterrent material disposed on a light-emitting surface of each micro-LED; and
a confinement material disposed around each micro-LED, wherein the confinement material does not cover any portion of the light-emitting surface of any micro-LED.
